(19) United States
(12) Patent Application Publication
(10) Pub. No.: US 2026/0051851 A1
(43) Pub. Date: Feb. 19, 2026

(54) Harmonic Conversion Gain Reduction for Mixer Circuitry

(71) Applicant: Apple Inc., Cupertino, CA (US)

(72) Inventor: Omar E Elaasar, San Diego, CA (US)

(21) Appl. No.: 19/202,644

(22) Filed: May 8, 2025

Related U.S. Application Data
(60) Provisional application No. 63/684,600, filed on Aug. 19, 2024.

(51) Int. Cl. H03D 7/14; H03D 7/16

(52) U.S. Cl. CPC H03D 7/1458; H03D 7/165; H03D 2200/0066; H03D 2200/0086

(57) ABSTRACT

Mixer circuitry can include a first mixer transistor configured to receive a first oscillating signal, a second mixer transistor configured to receive a second oscillating signal, and a harmonic conversion gain rejection filter coupled between a source terminal of the first mixer transistor and a source terminal of the second mixer transistor. The harmonic conversion gain rejection filter can be configured to reject a harmonic conversion gain of the mixer circuitry. The mixer circuitry can further include a third mixer transistor configured to receive the first oscillating signal, a fourth mixer transistor configured to receive the second oscillating signal, and another harmonic conversion gain rejection filter coupled between a source terminal of the third mixer transistor and a source terminal of the fourth mixer transistor. The mixer circuitry can further include an output transformer and a notch filter interposed between coils of the output transformer.

This application claims the benefit of U.S. Provisional Ser. No. 63/684,600, filed Aug. 19, 2024, which is hereby incorporated by reference herein in its entirety.

### FIELD

This disclosure relates generally to electronic devices and, more particularly, to electronic devices with wireless communications circuitry.

### BACKGROUND

Electronic devices are often provided with wireless communications capabilities. An electronic device with wireless communications capabilities has wireless communications circuitry with one or more antennas that are used to transmit radio-frequency signals and receive radio-frequency signals.

The wireless communications circuitry can include a transceiver having one or more mixers. A mixer in the transmit path can be used to modulate signals from a baseband frequency to a radio frequency, whereas a mixer in the receive path can be used to demodulate signals from the radio-frequency to the baseband frequency. Mixers receive clock signals generated from a local oscillator. It can be challenging to design satisfactory mixers for an electronic device.

### SUMMARY

An aspect of the disclosure provides mixer circuitry that includes a first mixer transistor configured to receive a first oscillating signal, a second mixer transistor configured to receive a second oscillating signal different than the first oscillating signal, and a harmonic conversion gain rejection filter coupled between a source terminal of the first mixer transistor and a source terminal of the second mixer transistor, wherein the harmonic conversion gain rejection filter is configured to reject a harmonic conversion gain of the mixer circuitry. The harmonic conversion gain rejection filter can include an inductor coupled between the source terminal of the first mixer transistor and the source terminal of the second mixer transistor, an adjustable capacitor coupled between the source terminal of the first mixer transistor and the source terminal of the second mixer transistor, a pair of cross-coupled transistors coupled between the source terminal of the first mixer transistor and the source terminal of the second mixer transistor and coupled to a tail node, and a current source coupled to the tail node. The current source can be selectively activated to enable the pair of cross-coupled transistors and is selectively deactivated to disable the pair of cross-coupled transistors.

The mixer circuitry can further include a first output coil coupled between a drain terminal of the first mixer transistor and a drain terminal of the second mixer transistor, a second output coil magnetically coupled to the first output coil and having opposing terminals configured as a differential output port of the mixer circuitry, and an additional harmonic conversion gain rejection filter interposed between the first and second output coils, where the additional harmonic conversion gain rejection filter is configured to reject the harmonic conversion gain of the mixer circuitry. The additional harmonic conversion gain rejection filter can include a filter coil magnetically coupled to at least the second output coil and an adjustable filter capacitor coupled in parallel with the filter coil.

An aspect of the disclosure provides mixer circuitry that includes first and second input transistors, a first pair of mixer transistors configured to receive an oscillating signal, a second pair of mixer transistors configured to receive the oscillating signal, and a first filter circuit coupled at source terminals of the first pair of mixer transistors, where the first filter circuit includes an inductor and a capacitor. The first filter circuit can further include a pair of cross-coupled transistors coupled to the inductor and the capacitor and an adjustable current source coupled to the pair of cross-coupled transistors. The mixer circuitry can further include an output transformer having a primary coil coupled between the first pair of mixer transistors and between the second pair of mixer transistors and having a secondary coil and an output filter circuit interposed between the primary coil and the secondary coil of the output transformer. The output filter can include a filter coil and a filter capacitor coupled in parallel with the filter coil.

An aspect of the disclosure provides mixer circuitry that includes a first pair of mixer transistors configured to receive an oscillating signal, a second pair of mixer transistors configured to receive the oscillating signal, an output transformer coupled to the first and second pairs of mixer transistors, the output transformer having a primary coil and a secondary coil, and a notch filter interposed between the primary coil and the secondary coil. The notch filter can be configured to suppress a harmonic conversion gain of the mixer circuitry. The mixer circuitry can further include a first LC filter coupled to source terminals of the first pair of mixer transistors, first active quality factor boosting components coupled to the first LC filter, a second LC filter coupled to source terminals of the second pair of mixer transistors, and second active quality factor boosting components coupled to the second LC filter.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having a transceiver in accordance with some embodiments.

FIG. 3 is a diagram of an illustrative mixer in a transmit path in accordance with some embodiments.

FIG. 4 is a diagram illustrating how a signal at an intermediate frequency can upconvert to a radio-frequency range of interest through a third harmonic conversion gain of a transmitting mixer in accordance with some embodiments.

FIG. 5 is a block diagram of illustrative mixer circuitry coupled to a single-phase local oscillator in accordance with some embodiments.

FIG. 6 is a circuit diagram of illustrative mixer circuitry of the type shown in FIG. 5 in accordance with some embodiments.

FIG. 7 is diagram plotting forward conversion gain as a function of frequency for various types of mixers in accordance with some embodiments.

### DETAILED DESCRIPTION

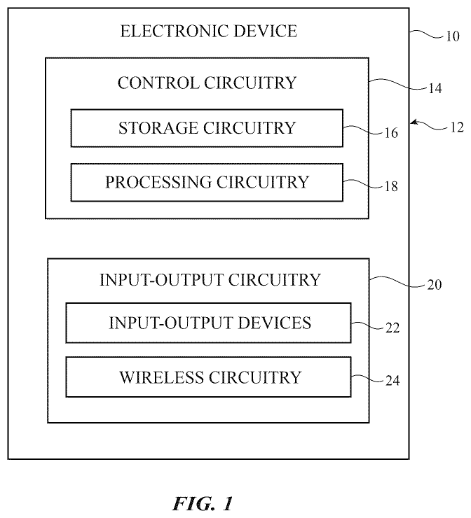

An electronic device such as electronic device 10 of FIG. 1 may be provided with wireless circuitry. The wireless circuitry may include one or more mixers such as a mixer in a transmit path for upconverting (modulating) signals from lower frequencies to higher frequencies and such as a mixer in a receive path for downconverting (demodulating) signals from higher frequencies to lower frequencies. A mixer can receive an oscillating (clock) signal from a local oscillator (LO). The oscillating signal can have an oscillation frequency sometimes referred to herein as the LO frequency. The mixer can shift a signal of interest around the LO frequency and its corresponding harmonics (e.g., at associated harmonic frequencies that are equal to an integer multiple of the LO frequency). For instance, the mixer can inadvertently convert the signal of interest around the third harmonic LO frequency, a phenomenon sometimes referred to herein as the mixer “third harmonic conversion gain.”

In accordance with some embodiments, a mixer can include two transistor pairs, passive LC (inductive and capacitive based) filters coupled at the source terminals of the transistor pairs to reject or mitigate the third harmonic conversion gain of the mixer, active quality (Q) factor boosting circuits configured to improve the third harmonic conversion gain rejection capabilities of the LC filters, and an output notch filter coupled to the mixer output terminals to further reduce the mixer third harmonic conversion gain. The term “LC” filter may refer to a filter circuit having at least inductive and capacitive components. Mixer circuitry configured in this way can be technically advantageous and beneficial to suppress undesired in-band spurs without incurring much area and power consumption and without requiring additional trimming and component matching requirements.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), cellular sidebands, 6G bands between 100-1000 GHz (e.g., sub-THz, THz, or THF bands), etc.), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

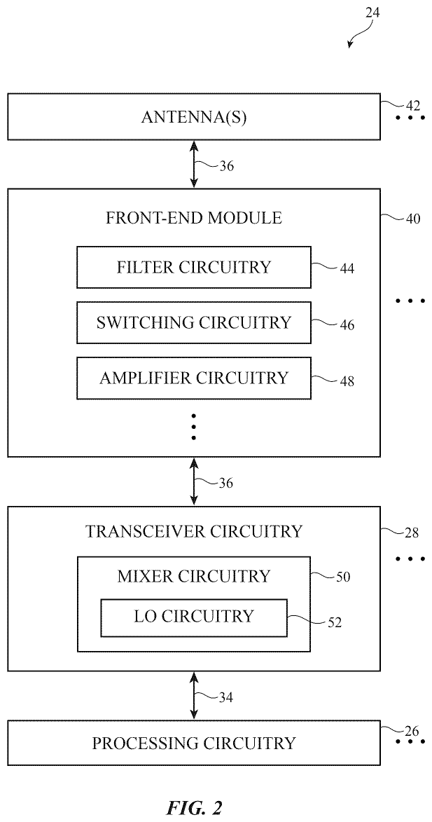

FIG. 2 is a diagram showing illustrative components within wireless circuitry 24. As shown in FIG. 2, wireless circuitry 24 may include processing circuitry such as processing circuitry 26, radio-frequency (RF) transceiver circuitry such as radio-frequency transceiver 28, radio-frequency front-end circuitry such as radio-frequency front-end module (FEM) 40, and antenna(s) 42. Processing circuitry 26 may include a baseband processor, an application processor, a digital signal processor, a microcontroller, a microprocessor, a central processing unit (CPU), a programmable device, a combination of these circuits, and/or one or more processors within circuitry 18. Processing circuitry 26 may be configured to generate digital (transmit or baseband) signals. Processing circuitry 26 may be coupled to transceiver 28 over path 34 (sometimes referred to as a baseband path). Transceiver 28 may be coupled to antenna 42 via radio-frequency transmission line path 36. Radio-frequency front-end module 40 may be disposed along radio-frequency transmission line path 36 between transceiver 28 and antenna 42.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

In the example of FIG. 2, wireless circuitry 24 is illustrated as including only a single processing unit 26, a single transceiver 28, a single front-end module 40, and a single antenna 42 for the sake of clarity. In general, wireless circuitry 24 may include any desired number of processing units 26, any desired number of transceivers 28, any desired number of front-end modules 40, and any desired number of antennas 42. Each processing unit 26 may be coupled to one or more transceiver 28 over respective paths 34. Each transceiver 28 may include a transmitter circuit configured to output uplink signals to antenna 42, may include a receiver circuit configured to receive downlink signals from antenna 42, and may be coupled to one or more antennas 42 over respective radio-frequency transmission line paths 36. Each radio-frequency transmission line path 36 may have a respective front-end module 40 disposed thereon. If desired, two or more front-end modules 40 may be disposed on the same radio-frequency transmission line path 36. If desired, one or more of the radio-frequency transmission line paths 36 in wireless circuitry 24 may be implemented without any front-end module interposed thereon.

Front-end module (FEM) 40 may include radio-frequency front-end circuitry that operates on the radio-frequency signals conveyed (transmitted and/or received) over radio-frequency transmission line path 36. Front-end module may, for example, include front-end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers and one or more low-noise amplifiers), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front-end module components may be mounted to a common (shared) substrate such as a rigid printed circuit board substrate or flexible printed circuit substrate. If desired, the various front-end module components may also be integrated into a single integrated circuit chip.

Filter circuitry 44, switching circuitry 46, amplifier circuitry 48, and other circuitry may be interposed within radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards. In one suitable arrangement, radio-frequency transmission line paths such as radio-frequency transmission line path 36 may also include transmission line conductors integrated within multilayer laminated structures (e.g., layers of a conductive material such as copper and a dielectric material such as a resin that are laminated together without intervening adhesive). The multilayer laminated structures may, if desired, be folded or bent in multiple dimensions (e.g., two or three dimensions) and may maintain a bent or folded shape after bending (e.g., the multilayer laminated structures may be folded into a particular three-dimensional shape to route around other device components and may be rigid enough to hold its shape after folding without being held in place by stiffeners or other structures). All of the multiple layers of the laminated structures may be batch laminated together (e.g., in a single pressing process) without adhesive (e.g., as opposed to performing multiple pressing processes to laminate multiple layers together with adhesive).

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

In performing wireless transmission, processing circuitry 26 may provide digital signals to transceiver 28 over path 34. Transceiver 28 may further include circuitry for converting the baseband signals received from processing circuitry 26 into corresponding intermediate frequency or radio-frequency signals. For example, transceiver circuitry 28 may include mixer circuitry 50 for up-converting (or modulating) the baseband signals to intermediate frequencies or radio frequencies prior to transmission over antenna 42. Transceiver circuitry 28 may also include digital-to-analog converter (DAC) and/or analog-to-digital converter (ADC) circuitry for converting signals between digital and analog domains. Transceiver 28 may include a transmitter component to transmit the radio-frequency signals over antenna 42 via radio-frequency transmission line path 36 and front-end module 40. Antenna 42 may transmit the radio-frequency signals to external wireless equipment by radiating the radio-frequency signals into free space.

In performing wireless reception, antenna 42 may receive radio-frequency signals from external wireless equipment. The received radio-frequency signals may be conveyed to transceiver 28 via radio-frequency transmission line path 36 and front-end module 40. Transceiver 28 may include circuitry for converting the received radio-frequency signals into corresponding intermediate frequency or baseband signals. For example, transceiver 28 may use mixer circuitry 50 for downconverting (or demodulating) the received radio-frequency signals to baseband frequencies prior to conveying the received signals to processing circuitry 26 over path 34. Mixer circuitry 50 can include local oscillator circuitry such as local oscillator (LO) circuitry 52. Local oscillator circuitry 52 can generate oscillator (oscillating) signals that mixer circuitry 50 uses to modulate transmitting signals from baseband frequencies to radio frequencies and/or to demodulate the received signals from radio frequencies to baseband frequencies.

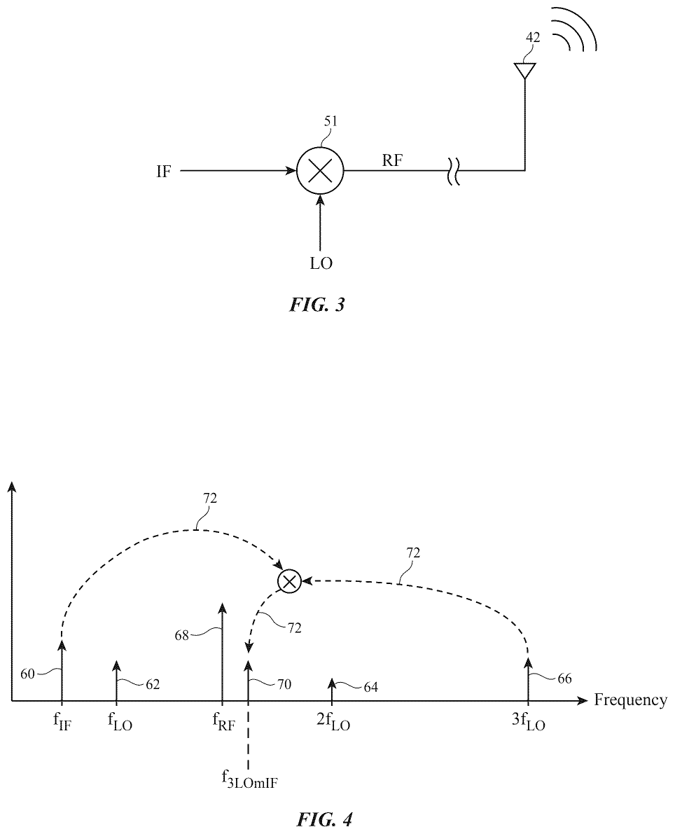

FIG. 3 is a diagram of an illustrative mixer in a transmit (TX) path of the wireless circuitry. As shown in FIG. 3, mixer 51 may output radio-frequency signals that are ultimately radiated by antenna 42. Mixer 51 in the transmit (uplink) path may be referred to as a transmitting mixer. Mixer 51 may represent one or more transmitting mixers in mixer circuitry 50 shown in FIG. 2. Transmitting mixer 51 may have a first input configured to receive a signal in the intermediate frequency (IF) range, a second input configured to receive an oscillating signal LO, and an output on which a modulated signal that is upconverted to a radio frequency (RF) range is generated (as an example). The oscillating signal, sometimes referred to as the LO signal, can have an oscillation frequency sometimes referred to herein as the LO frequency f_{LO}. One or more components such as a radio-frequency coupler, filter circuitry, antenna tuning element(s), matching network(s), switching circuitry, amplifier circuitry, other radio-frequency front-end components, other transceiver components, and/or other wireless components can be disposed in the transmit path between transmitting mixer 51 and antenna 42. Transmitting mixer 51 that outputs a radio-frequency signal can be referred to as a radio-frequency mixer.

FIG. 4 is a diagram illustrating how a third harmonic conversion gain of a transmitting mixer 51 can generate undesired in-band emissions at the mixer output. In general, mixer 51 can shift a signal of interest (e.g., a signal at an IF frequency f_{IF}) around the LO frequency f_{LO}. As an example, the ratio of signal amplitudes at frequency (f_{LO}±f_{IF}) to signal amplitudes at frequency f_{IF} can be defined herein as a mixer “fundamental conversion gain” or transfer function. As another example, the ratio of signal amplitudes at frequency (3*f_{LO}±f_{IF}) to signal amplitudes at frequency f_{IF} can be defined herein as a mixer “third harmonic conversion gain” or transfer function. More generally, the ratio of signal amplitudes at frequency (N*f_{LO}±f_{IF}) to signal amplitudes at frequency f_{IF} can be defined herein as an N^{th} order “harmonic conversion gain” or transfer function (or more generically as a “harmonic conversion gain”) of a mixer. It is generally desired to maximize the fundamental conversion gain while minimizing the harmonic conversion gains for N greater than one (e.g., to mitigate or reject the second harmonic conversion gain, the third harmonic conversion gain, the fourth harmonic conversion gain, the fifth harmonic conversion gain, etc.).

As shown in FIG. 4, the intermediate frequency signal 60 received at the first input of mixer 51 can be located at frequency f_{IF}; the LO signal 62 received at the second input of mixer 51 can be located at frequency f_{LO}; and the modulated signal 68 generated at the output of mixer 51 can be located at radio frequency f_{RF}. In practice, the local oscillator feeding the second input of transmitting mixer 51 can exhibit non-linear behavior that results in generation of a second harmonic component 64 at frequency 2*f_{LO}, a third harmonic component 66 at frequency 3*f_{LO}, and/or other harmonic components. In the example of FIG. 4, the third harmonic LO component 66 can mix with the signal of interest 60 and generate an corresponding interfering signal 70 that can fall in the radio-frequency range of interest (see, e.g., arrows 72 landing at frequency f_{3LOmIF}, where f_{3LOmIF} is equal to 3*f_{LO} minus f_{IF}). As described above, this phenomenon can be referred to as being caused by the third harmonic conversion gain of mixer 51. The frequency f_{3LOmIF} of the interfering signal 70 can be problematic if the selection of the radio-frequency f_{RF} and the local oscillator frequency f_{LO} results in the interfering signal 70 falling within or close to the radio-frequency (RF) range of interest, as illustrated in the example of FIG. 4. In some examples, signal 70 may interfere with the radio-frequency signal 68 of interest at f_{RF} at the output of transmitting mixer 51, which can result in the transmit path violating performance criteria.

The scenario illustrated in FIGS. 3 and 4 relating to mixer 51 in a transmit path is exemplary. The embodiments described herein can additionally or alternatively be applied to a mixer in a receive path (e.g., a path for receiving and processing radio-frequency signals received by antenna 42). A mixer in the receive path can also exhibit harmonic conversion gain such as the third harmonic conversion gain that produces spurious in-band signals that can potentially degrade the performance of the receive path.

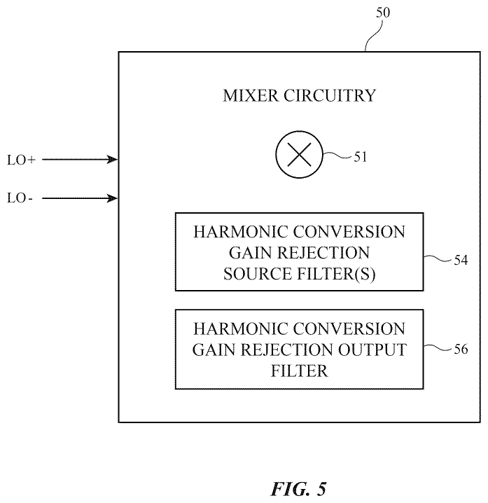

In accordance with an embodiment, mixer circuitry 50 is provided with harmonic conversion gain rejection capabilities (see, e.g., FIG. 5). As shown in FIG. 5, mixer circuitry 50 can include a mixer circuit such as mixer circuit 51 and one or more filters such as filter(s) 54 and filter 56. Mixer circuit 51 can include two pairs of mixing transistors. Mixer circuit 51 can be configured to receive a differential LO signal, which can include LO+and LO−. Filter(s) 54 can include one or more harmonic conversion gain rejection filters coupled to source terminals of the mixing transistors. Filters 54 can thus sometimes be referred to herein as harmonic conversion gain rejection “source” filters. Filter 56 can be coupled to an output (load) of mixer circuit 51. As such, filter 56 can thus sometimes be referred to herein as a harmonic conversion gain rejection “output” filter. The term “harmonic conversion gain rejection” can refer to and be defined herein as an act of rejecting, filtering, suppressing, or otherwise mitigating the N^{th} harmonic conversion gain of the mixer, where N can be equal to 2, 3, 4, 5, or other integer value.

The embodiment of FIG. 5 where circuitry 50 includes only one mixer circuit 51 with two pairs of mixing transistors configured to receive one differential LO signal is sometimes referred to as “single-phase” mixer circuitry. In contrast, a multi-phase mixer can be configured to receive multiple LO signals of different phases. For instance, a multi-phase mixer might include a first portion configured to receive a first LO signal, a second portion configured to receive a second LO signal phase shifted by 120 degrees relative to the first LO signal, and a third portion that receives a third LO signal phase signed by 240 degrees relative to the first LO signal. Such type of “multi-phase” mixer can be configured to reject the mixer third harmonic conversion gain but requires multiple local oscillator driving buffers, multiple digital-to-analog converters (DACs) for gain scaling, multiple phase calibration, additional trimming of DC offsets among the various mixer portions, additional area to accommodate more mixing components, and consumes more power.

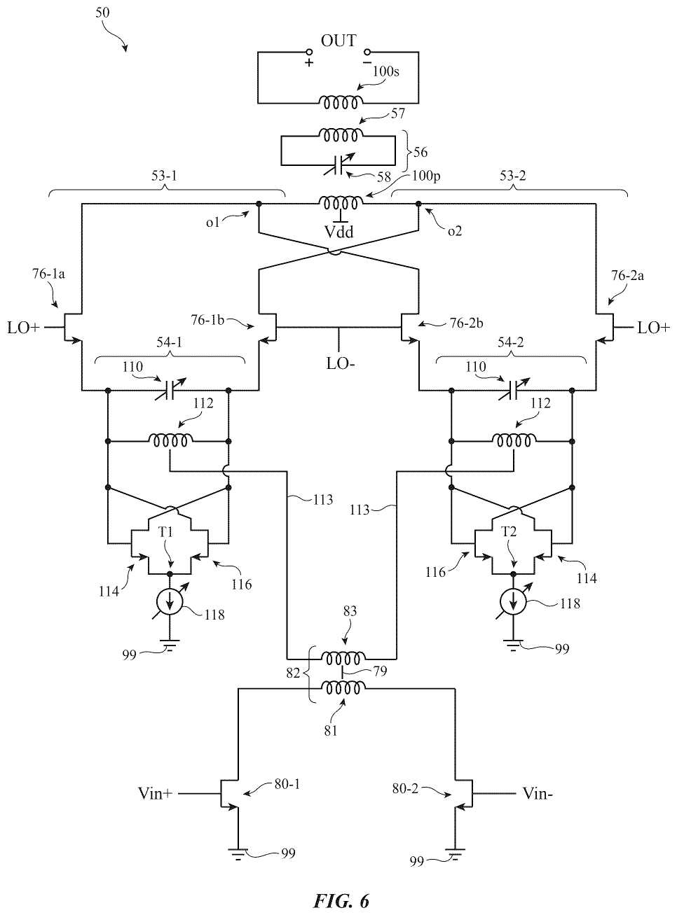

FIG. 6 is a circuit diagram of illustrative single-phase mixer circuitry 50 of the type described in connection with at least FIG. 5. Mixer circuitry 50 can represent a transmitting mixer (e.g., a mixer in a transmit path) or a receiving mixer (e.g., a mixer in a receive path). As shown in FIG. 6, mixer circuitry 50 may include a first input transistor 80-1 and a second input transistor 80-2 coupled to an input transformer such as transformer 82. Transformer 82 can include a primary coil (winding) 81 and a secondary coil (winding) 83. Primary coil 81 can have a center tap that is shorted to the center tap of secondary coil 83, as shown by center tap connection 79. Connecting together the center tap terminals of coils 81 and 83 in this way allows current to be shared or reused between the two coils. Transformer 82 configured in this way is therefore sometimes referred to as a “current reuse” transformer. Current reuse transformer 82 is optional and can be omitted, if desired.

Input transistors 80-1 and 80-2 can be n-channel devices such as n-type metal-oxide-semiconductor (NMOS) transistors. The first input transistor 80-1 may have a drain terminal coupled to a first terminal of coil 81, a source terminal coupled to a ground power supply line 99 (e.g., a ground line on which a ground voltage is provided), and a gate terminal configured to receive input voltage Vin+. The second input transistor 80-2 may have a drain terminal coupled to a second terminal of coil 81, a source terminal coupled to ground line 68, and a gate terminal configured to receive input voltage Vin−. The delta of voltages Vin+ and Vin-may represent the differential radio-frequency input signal of mixer circuitry 50. The terms “source” and “drain” are sometimes used interchangeably when referring to current-conducting terminals of a metal-oxide-semiconductor transistor. The source and drain terminals are therefore sometimes referred to as “source-drain” terminals (e.g., a transistor has a gate terminal, a first source-drain terminal, and a second source-drain terminal). Thus, the drain terminal of transistor 80-1 can sometimes be referred to as a first source-drain terminal, and the source terminal of transistor 80-1 can be referred to as a second source-drain terminal (or vice versa).

The term “activate” with respect to a switch (or transistor) may refer to or be defined herein as an action that places the switch in an “on” or low-impedance state such that the two terminals of the switch are electrically connected to conduct current. Activating a switch can sometimes be referred to as turning on or closing a switch. The term “deactivate” with respect to a switch (or transistor) may refer to or be defined herein as an action that places the switch in an “off” or high-impedance state such that the two terminals of the switch/transistor are electrically disconnected with minimal leakage current. Deactivating a switch can sometimes be referred to as turning off or opening a switch.

Transformer 82 may be coupled to mixer subcircuits 53-1 and 53-2. Mixer subcircuit 53-1 can include a first pair of mixer transistors 76-1a and 76-1b (e.g., a first transistor pair). Mixer transistor 76-1a may have a source terminal, a gate terminal configured to receive signal LO+, and a drain terminal coupled to a node o1. Mixer transistor 76-1b may have a source terminal, a gate terminal configured to receive signal LO−, and a drain terminal cross-coupled to a node o2. Signals LO+ and LO− represent the positive and negative polarities of a differential signal and can collectively be referred to as a local oscillator (LO) signal or an oscillating signal. The gate terminals of mixer transistors 76-1a and 76-1b collectively form a differential input port for receiving the LO signal. A load inductor (coil) 100p can be coupled across nodes o1 and o2. In particular, load inductor 100p may have a first terminal coupled to node o1 and a second terminal coupled to node o2.

Mixer subcircuit 53-2 can include a second pair of mixer transistors 76-2a and 76-2b (e.g., a second transistor pair). Mixer transistor 76-2a may have a source terminal, a gate terminal configured to receive signal LO+, and a drain terminal coupled to node o2. Mixer transistor 76-2b may have a source terminal, a gate terminal configured to receive signal LO−, and a drain terminal cross-coupled to node o1. The gate terminals of mixer transistors 76-2a and 76-2b collectively form a differential input for receiving the LO signal.

In accordance with an embodiment, a capacitor 110 and an inductor 112 can be coupled across the source terminals of mixer transistors 76-1a and 76-1b. In particular, capacitor 110 can have a first terminal coupled to the source terminal of transistor 76-1a and a second (opposing) terminal coupled to the source terminal of transistor 76-1b. Similarly, inductor 112 can have a first terminal coupled to the source terminal of transistor 76-1a, a second (opposing) terminal coupled to the source terminal of transistor 76-1b, and a center tap terminal coupled to secondary coil 83 via path 113. If transformer 82 were omitted, then the center tap of inductor 112 would be directly coupled to the drain terminal of first input transistor 80-1. Capacitor 110 can, for example, be an adjustable capacitor implemented as a bank of switchable capacitors (e.g., an array of capacitors each of which is selectively activated by a respective switch), a variable capacitor sometimes referred to as a varactor, a varicap diode, a metal-oxide-semiconductor capacitor (MOSCAP), and/or other components configured to provide a variable capacitance. Components 110 and 112 coupled to the source terminals of transistors 76-1a and 76-1b can formed part of a harmonic conversion gain rejection source filter 54-1 within mixer circuitry 50. In other words, components 110 and 112 can be configured as an LC filter (tank) circuit for reducing the third harmonic conversion gain of the mixer.

At the other side, another capacitor 110 and another inductor 112 can be coupled across the source terminals of mixer transistors 76-2a and 76-2b. In particular, capacitor 110 can have a first terminal coupled to the source terminal of transistor 76-2a and a second (opposing) terminal coupled to the source terminal of transistor 76-2b. Similarly, inductor 112 can have a first terminal coupled to the source terminal of transistor 76-2a, a second (opposing) terminal coupled to the source terminal of transistor 76-2b, and a center tap terminal coupled to coil 83 via path 113. If transformer 82 were omitted, then the center tap of inductor 112 would be directly coupled to the drain terminal of second input transistor 80-2. Capacitor 110 can, for example, be an adjustable capacitor implemented as a bank of switchable capacitors (e.g., an array of capacitors each of which is selectively activated by a respective switch), a variable capacitor sometimes referred to as a varactor, a varicap diode, a metal-oxide-semiconductor capacitor (MOSCAP), and/or other components configured to provide a variable capacitance. Components 110 and 112 coupled to the source terminals of transistors 76-2a and 76-2b can formed part of another harmonic conversion gain rejection source filter 54-2 within mixer circuitry 50. In other words, components 110 and 112 can be configured as an LC filter (tank) circuit for reducing the third harmonic conversion gain of the mixer.

The use of purely passive LC components 110 and 112 for harmonic conversion gain filtering can exhibit a limited filter quality (Q) factor. To help further improve the filter Q factor, the harmonic conversion gain rejection source filter 54 can optionally be provided with active circuitry, including active components 114, 116, and 118. Shown as part of harmonic conversion gain rejection source filter 54-1, transistor 114 (e.g., an n-type or NMOS device) can have a gate terminal coupled to the source terminal of mixer transistor 76-1a, a drain terminal cross-coupled to the source terminal of mixer transistor 76-1b, and a source terminal coupled to a tail node T1; transistor 116 (e.g., an n-type or NMOS device) can have a gate terminal coupled to the source terminal of mixer transistor 76-1b, a drain terminal cross-coupled to the source terminal of mixer transistor 76-1a, and a source terminal coupled to tail node T1; and a current source 118 coupled between tail node T1 and ground line 99. Current source 118 can be an adjustable current source that is selectively activated to enable the operation of the pair of cross-coupled transistors 114 and 116 and selectively deactivated to disable the operation of the pair of cross-coupled transistors 114 and 116. When current source 118 is activated, harmonic conversion gain rejection source filter 54-1 can provide an improved filter Q factor, which improves the third harmonic conversion gain suppression while boosting the fundamental gain. Components 114, 116, and 118 are therefore sometimes referred to collectively herein as active quality factor boosting components.

At the other side and shown as part of the other harmonic conversion gain rejection source filter 54-2, transistor 114 (e.g., an n-type or NMOS device) can have a gate terminal coupled to the source terminal of mixer transistor 76-2a, a drain terminal cross-coupled to the source terminal of mixer transistor 76-2b, and a source terminal coupled to a tail node T2; transistor 116 (e.g., an n-type or NMOS device) can have a gate terminal coupled to the source terminal of mixer transistor 76-2b, a drain terminal cross-coupled to the source terminal of mixer transistor 76-2a, and a source terminal coupled to tail node T2; and a current source 118 coupled between tail node T2 and ground line 99. Current source 118 can be selectively activated to enable the operation of the associated cross-coupled transistors 114 and 116 and can be selectively deactivated to disable the operation of the associated cross-coupled transistors 114 and 116. When current source 118 is activated, harmonic conversion gain rejection source filter 54-2 can provide an improved filter Q factor, which improves the third harmonic conversion gain suppression while boosting the fundamental gain.

At the output side of mixer circuitry 50, load inductor 100p can be magnetically coupled to a corresponding output inductor 100s. Output inductor 100s can have opposing terminals coupled to a differential output port OUT of mixer circuitry 50. Arranged in this way, inductors 100p and 100s can operate as part of an output transformer, where inductor 100p is part of a primary coil (winding) of the output transformer and where inductor 100s is part of a secondary coil (winding) of the output transformer. Load inductor 100p can have a center tap configured to receive a positive power supply voltage Vdd (e.g., inductor 100p has a center tap terminal coupled to a power supply line such as a positive power supply terminal).

In accordance with some embodiments, the output transformer can further include harmonic conversion gain rejection output filter 56. As shown in the example of FIG. 6, harmonic conversion gain rejection output filter 56 can include an inductor 57 and a capacitor 58. Inductor (coil) 57 may be magnetically coupled to inductor 100s and/or inductor 100p. Inductor 57 can have opposing terminals respectively coupled to opposing terminals of capacitor 58 (e.g., inductor 57 and capacitor 58 are coupled together “in parallel”). Capacitor 58 can, for example, be an adjustable capacitor implemented as a bank of switchable capacitors (e.g., an array of capacitors each of which is selectively activated by a respective switch), a variable capacitor sometimes referred to as a varactor, a varicap diode, a metal-oxide-semiconductor capacitor (MOSCAP), and/or other components configured to provide a variable capacitance.

Configured in this way, harmonic conversion gain rejection output filter 56 can help further suppress the third harmonic conversion gain of the mixer. Operated in this way, inductor 57 can be referred to herein as a filter coil or a harmonic conversion gain rejection coil, whereas capacitor 58 can be referred to herein as a filter capacitor or a harmonic conversion gain rejection capacitor. Filter 56 can be a notch filter (as an example), and capacitor 58 can be adjusted to tune a notch frequency, sometimes also referred to as a rejection frequency or null frequency, of filter 56.

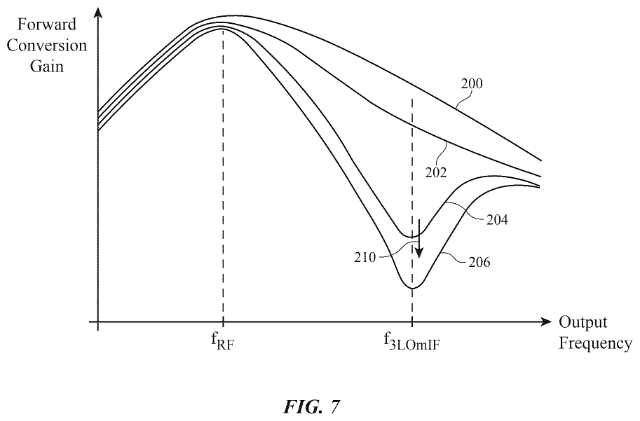

FIG. 7 is diagram plotting forward conversion gain as a function of output frequency for various types of mixers in accordance with some embodiments. Curve 200 may represent the forward conversion gain profile of a mixer without any harmonic conversion gain rejection source filters 54 and without harmonic conversion gain rejection output filter 56. Curve 202 may represent the forward conversion gain profile of mixer circuitry that includes harmonic conversion rejection output filter 56 but does not include any harmonic conversion gain rejection source filters 54. Curve 204 may represent the forward conversion gain profile of mixer circuitry that includes harmonic conversion gain rejection source filters 54 but does not include a harmonic conversion rejection output filter 56. Curve 206 may represent the forward conversion gain profile of mixer circuitry 50 that includes harmonic conversion gain rejection source filters 54 and also harmonic conversion rejection output filter 56 (as shown in the example of FIG. 6).

As shown in FIG. 7, curve 202 provides improved third harmonic conversion gain rejection at frequency f_{3LOmIF}, relative to curve 200, while maintaining the gain at output fundamental frequency f_{RF}. Moreover, curve 204 provides further improved third harmonic conversion gain rejection at frequency f_{3LOmIF}, relative to curve 202, while maintaining the gain at output fundamental frequency f_{RF}. Lastly, curve 206 provides further improved third harmonic conversion gain rejection at frequency f_{3LOmIF}, relative to curve 204 (as annotated by arrow 210), while maintaining the gain at output fundamental frequency f_{RF}. In other words, the use of harmonic conversion gain rejection source filters 54 and/or harmonic conversion gain rejection output filter 56 within mixer circuitry 50 can be technically advantageous and beneficial to maximize the (third) harmonic conversion gain rejection.

The methods and operations described above in connection with FIGS. 1-7 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is illustrative and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. Mixer circuitry comprising:
a first mixer transistor configured to receive a first oscillating signal;
a second mixer transistor configured to receive a second oscillating signal different than the first oscillating signal; and
a harmonic conversion gain rejection filter coupled between a source terminal of the first mixer transistor and a source terminal of the second mixer transistor, wherein the harmonic conversion gain rejection filter is configured to reject a harmonic conversion gain of the mixer circuitry.

2. The mixer circuitry of claim 1, further comprising:
a third mixer transistor configured to receive the first oscillating signal;
a fourth mixer transistor configured to receive the second oscillating signal; and
an additional harmonic conversion gain rejection filter coupled between a source terminal of the third mixer transistor and a source terminal of the fourth mixer transistor.

3. The mixer circuitry of claim 2, further comprising:
a first input transistor configured to receive a first input voltage and coupled to the harmonic conversion gain rejection filter; and
a second input transistor configured to receive a second input voltage and coupled to the additional harmonic conversion gain rejection filter.

4. The mixer circuitry of claim 3, further comprising:
a input transformer that includes
a primary coil having a first terminal coupled to the first input transistor and having a second terminal coupled to the second input transistor, and
a secondary coil having a first terminal coupled to the harmonic conversion gain rejection filter and having a second terminal coupled to the additional harmonic conversion gain rejection filter.

5. The mixer circuitry of claim 4, wherein:
the first terminal of the secondary coil is coupled to a center tap of an inductor in the harmonic conversion gain rejection filter; and
the second terminal of the secondary coil is coupled to a center tap of an inductor in the additional harmonic conversion gain rejection filter.

6. The mixer circuitry of claim 1, wherein the harmonic conversion gain rejection filter comprises:
an inductor coupled between the source terminal of the first mixer transistor and the source terminal of the second mixer transistor.

7. The mixer circuitry of claim 6, wherein the harmonic conversion gain rejection filter further comprises:
an adjustable capacitor coupled between the source terminal of the first mixer transistor and the source terminal of the second mixer transistor.

8. The mixer circuitry of claim 7, wherein the harmonic conversion gain rejection filter further comprises:
a pair of cross-coupled transistors coupled between the source terminal of the first mixer transistor and the source terminal of the second mixer transistor and coupled to a tail node.

9. The mixer circuitry of claim 8, wherein the harmonic conversion gain rejection filter further comprises:
a current source coupled to the tail node, the current source configured to be selectively activated to enable the pair of cross-coupled transistors and selectively deactivated to disable the pair of cross-coupled transistors.

10. The mixer circuitry of claim 1, further comprising:
a first output coil having a first terminal coupled to a drain terminal of the first mixer transistor, a second terminal coupled to a drain terminal of the second mixer transistor, and a center tap configured to receive a power supply voltage;
a second output coil magnetically coupled to the first output coil and having opposing terminals configured as a differential output port of the mixer circuitry; and
an additional harmonic conversion gain rejection filter interposed between the first and second output coils, wherein the additional harmonic conversion gain rejection filter is configured to reject the harmonic conversion gain of the mixer circuitry.

11. The mixer circuitry of claim 10, wherein the additional harmonic conversion gain rejection filter comprises:
a filter coil magnetically coupled to at least the second output coil.

12. The mixer circuitry of claim 11, wherein the additional harmonic conversion gain rejection filter further comprises:
an adjustable filter capacitor coupled in parallel with the filter coil.

13. The mixer circuitry of claim 1, wherein the harmonic conversion gain rejection filter is configured to reject a third harmonic conversion gain of the mixer circuitry.

14. Mixer circuitry comprising:
first and second input transistors;
a first pair of mixer transistors configured to receive an oscillating signal;
a second pair of mixer transistors configured to receive the oscillating signal; and
a first filter circuit coupled at source terminals of the first pair of mixer transistors,
wherein the first filter circuit comprises an inductor and a capacitor.

15. The mixer circuitry of claim 14, further comprising:
a second filter circuit coupled at source terminals of the second pair of mixer transistors, wherein the second filter circuit comprises an inductor and a capacitor.

16. The mixer circuitry of claim 15, wherein:
the inductor of the first filter circuit has a center tap coupled to the first input transistor; and
the inductor of the second filter circuit has a center tap coupled to the second input transistor.

17. The mixer circuitry of claim 14, wherein the first filter circuit further comprises:
a pair of cross-coupled transistors coupled to the inductor and the capacitor; and
an adjustable current source coupled to the pair of cross-coupled transistors.

18. The mixer circuitry of claim 14, further comprising:
an output transformer having a primary coil coupled between the first pair of mixer transistors and between the second pair of mixer transistors and having a secondary coil; and
an output filter circuit interposed between the primary coil and the secondary coil of the output transformer, wherein the output filter comprises a filter coil and a filter capacitor coupled in parallel with the filter coil.

19. Mixer circuitry comprising:
a first pair of mixer transistors configured to receive an oscillating signal;
a second pair of mixer transistors configured to receive the oscillating signal;
an output transformer coupled to the first and second pairs of mixer transistors, the output transformer having a primary coil and a secondary coil; and
a notch filter interposed between the primary coil and the secondary coil, wherein the notch filter is configured to suppress a harmonic conversion gain of the mixer circuitry.

20. The mixer circuitry of claim 19, further comprising:
a first LC filter coupled to source terminals of the first pair of mixer transistors;
first active quality factor boosting components coupled to the first LC filter;
a second LC filter coupled to source terminals of the second pair of mixer transistors; and
second active quality factor boosting components coupled to the second LC filter.
